(19) United States
(12) Patent Application Publication
(10) Pub. No.: US 2014/0209984 A1
(43) Pub. Date: Jul. 31, 2014

(54) Semiconductor Device With Multi Level Interconnects And Method Of Forming The Same

(71) Applicant: Taiwan Semiconductor Manufacturing Company, Ltd., (US)

(72) Inventors: Jeng Min Liang, Pingtung City (TW); Ying-Lang Wang, Tai-Chung County (TW); Kei-Wei Chen, Tainan City (TW); Chi-Wen Liu, Hsinchu (TW); Kuo-Hsiu Wei, Tainan City (TW); Kuo-Feng Huang, Tainan City (TW)

(73) Assignee: Taiwan Semiconductor Manufacturing Company, Ltd, Hsin-Chu (TW)

(21) Appl. No.: 13/756,389

(22) Filed: Jan. 31, 2013

(51) Int. Cl. H01L 23/485; H01L 21/768

(52) U.S. Cl. CPC H01L 23/485; H01L 21/76801
USPC 257/288; 438/622

(57) ABSTRACT

A semiconductor device and method for fabricating a semiconductor device is disclosed. An exemplary semiconductor device includes a substrate including a gate structure separating source and drain (S/D) features. The semiconductor device further includes a first dielectric layer formed over the substrate, the first dielectric layer including a first interconnect structure in electrical contact with the S/D features. The semiconductor device further includes an intermediate layer formed over the first dielectric layer, the intermediate layer having a top surface that is substantially coplanar with a top surface of the first interconnect structure. The semiconductor device further includes a second dielectric layer formed over the intermediate layer, the second dielectric layer including a second interconnect structure in electrical contact with the first interconnect structure and a third interconnect structure in electrical contact with the gate structure.

### BACKGROUND

The semiconductor integrated circuit (IC) industry has experienced rapid growth. In the course of the IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed.

For example, as the semiconductor industry has progressed into nanometer technology process nodes in pursuit of higher device density, higher performance, and lower costs, challenges from both fabrication and design have resulted in the development of manufacturing different types of integrated circuit devices on a single substrate. However, as the scaling down continues, forming interconnects for the different types of integrated circuit devices on a single substrate has proved difficult. Accordingly, although existing integrated devices and methods of fabricating integrated circuit devices have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart illustrating a method of fabricating a semiconductor device according to various aspects of the present disclosure.

FIGS. 2-18 illustrate diagrammatic cross-sectional side views of one embodiment of a semiconductor device at various stages of fabrication, according to the method of FIG. 1.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Also, the components disclosed herein may be arranged, combined, or configured in ways different from the exemplary embodiments shown herein without departing from the scope of the present disclosure. It is understood that those skilled in the art will be able to devise various equivalents that, although not explicitly described herein, embody the principles of the present invention.

Modern semiconductor devices may utilize interconnects to perform electrical routing between the various components and features on a semiconductor wafer and to establish electrical connections with external devices. The interconnect structure may include a plurality of vias/contacts that provide electrical connections between metal lines from different interconnect layers. As semiconductor device fabrication technologies continue to evolve, the sizes of the various features on a semiconductor device become smaller and smaller, including the sizes of the vias and metal lines that form interconnects. This leads to fabrication challenges. For example, the formation of interconnects may involve one or more lithography, etching, and deposition processes. Variations associated with these processes (e.g., variation in topography, critical dimension uniformity variations, or lithography overlay errors), adversely affects the performance of the semiconductor device. Alternatively stated, the device scaling down process may place a more stringent requirement on the manufacturing process used to form interconnects. Therefore, a method of manufacturing and a device that does not suffer from the above noted problems is desired.

According to the various aspects of the present disclosure, a semiconductor device including an interconnect structure is disclosed. The interconnect structure contains multiple metal layers. The method of forming the multiple metal layers may allow for, among other things, a reduction in manufacturing variation by improving topography and critical dimensions of the semiconductor device. The various aspects of the semiconductor device including such an interconnect structure is described in more detail below.

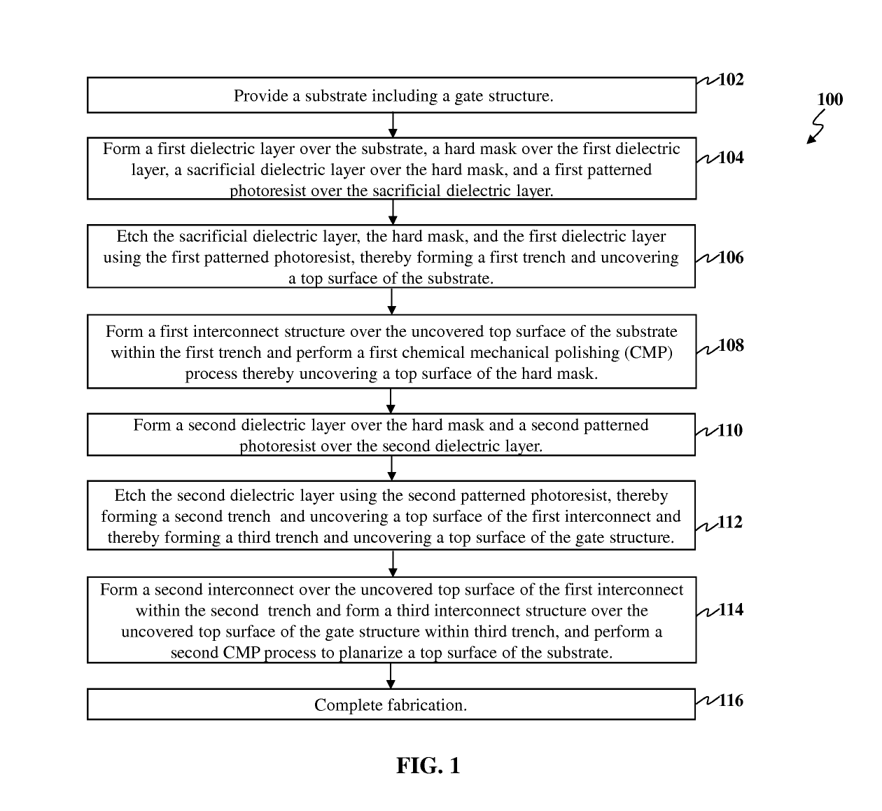

With reference to FIGS. 1 and 2-18, a method 100 and semiconductor device 200 are collectively described below. FIG. 1 is a flow chart of a method 100 for fabricating an integrated circuit device according to various aspects of the present disclosure. The method 100 begins at block 102 where a substrate including a substrate including a gate structure is provided. The substrate may include source and drain S/D features on either side of the gate structure. At block 104, a first dielectric layer is formed over the substrate, a hard mask is formed over the first dielectric layer, a sacrificial dielectric layer is formed over the hard mask, and a first patterned photoresist is formed over the sacrificial dielectric layer. The method continues with block 106 where the sacrificial dielectric layer, the hard mask, and the first dielectric layer are etched using the first patterned photoresist, thereby forming a first trench and uncovering a top surface of the substrate. The method continues with block 108 where a first interconnect structure is formed over the uncovered top surface of the substrate within the first trench and a first chemical mechanical polishing (CMP) process is performed on the substrate, thereby uncovering a top surface of the hard mask and planarizing a top surface of the substrate. At block 110, a second dielectric layer is formed over the hard mask and a second patterned photoresist is formed over the second dielectric layer. The method continues with block 112 where the second dielectric layer is etched using the second patterned photoresist, thereby forming a second trench and uncovering a top surface of the first interconnect and thereby forming a third trench and uncovering a top surface of the gate structure. At block 114, a second interconnect is formed over the uncovered top surface of the first interconnect within the second trench and a third interconnect structure is formed over the uncovered top surface of the gate structure within third trench, and a second CMP process is performed to planarize a top surface of the substrate. The method 100 continues with block 116 where fabrication of the integrated circuit device is completed. Additional steps can be provided before, during, and after the method 100, and some of the steps described can be replaced or eliminated for other embodiments of the method. The discussion that follows illustrates various embodiments of a semiconductor device 200 that can be fabricated according to the method 100 of FIG. 1.

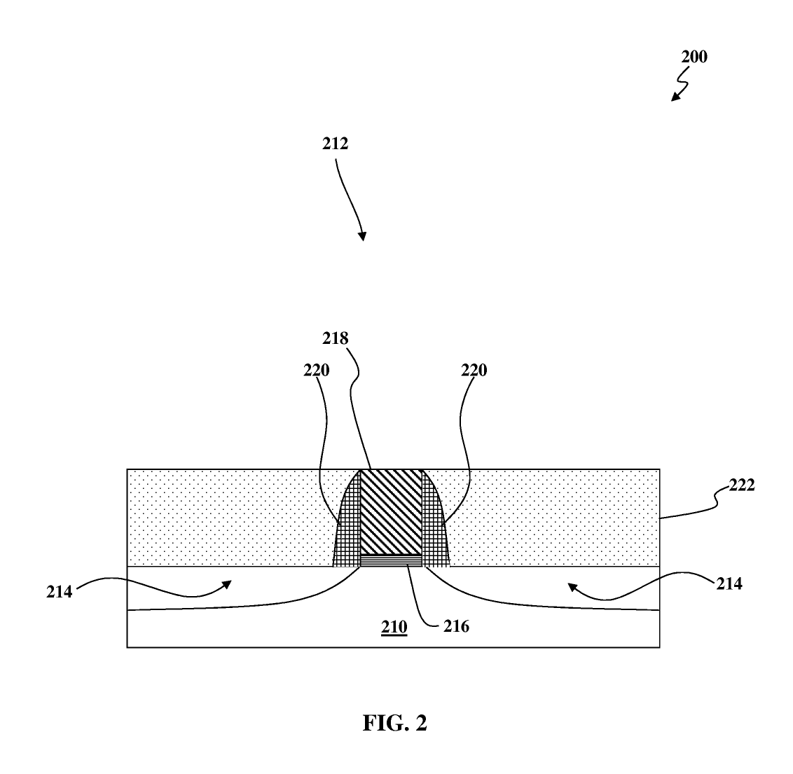

FIGS. 2-18 illustrate diagrammatic top and cross-sectional side views of one embodiment of a semiconductor device 200 at various stages of fabrication, according to the method of FIG. 1. It is understood that the semiconductor device 200 may include various other devices and features, such as transistors such as bipolar junction transistors, resistors, capacitors, diodes, fuses, etc. Accordingly, FIGS. 2-18 have been simplified for the sake of clarity to better understand the inventive concepts of the present disclosure. Additional features can be added in the semiconductor device 200 and some of the features described below can be replaced or eliminated in other embodiments of the semiconductor device 200.

Referring to FIG. 2, a diagrammatic cross-sectional side view of a semiconductor device is illustrated. The semiconductor device 200 includes a substrate 210. The substrate 210, for example, can be a bulk substrate or a silicon-on-insulator (SOI) substrate. The substrate may comprise an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; or combinations thereof. The SOI substrate can be fabricated using separation by implantation of oxygen (SIMOX), wafer bonding, and/or other suitable methods. The substrate 210 may include various doped regions and other suitable features. It is understood, that although the present disclosure provides an exemplary substrate, the scope of the disclosure and claims should not be limited to the specific example unless expressly claimed.

Still referring to FIG. 2, the substrate 210 includes a gate structure 212 traversing a channel region having source/drain (S/D) features 214 formed on either side. The S/D features may include lightly doped S/D features and heavy doped S/D features. The S/D features may be formed by implanting p-type or n-type dopants or impurities into the substrate 210. S/D features 214 may be formed by methods including thermal oxidation, polysilicon deposition, photolithography, ion implantation, etching, and various other methods. S/D features 214 may be raised S/D features formed by an epitaxy process.

Still referring to FIG. 2, the gate structure 212 may include a gate dielectric layer 216 including an interfacial layer/high-k dielectric layer formed over the substrate 210. The interfacial layer may include a silicon oxide layer (SiO2) or silicon oxynitride (SiON) formed on the substrate 210. The high-k dielectric layer may be formed on the interfacial layer by atomic layer deposition (ALD) or other suitable technique. The high-k dielectric layer may include hafnium oxide (HfO2). Alternatively, the high-k dielectric layer may optionally include other high-k dielectrics, such as TiO2, HfZrO, Ta2O3, HfSiO4, ZrO2, ZrSiO2, combinations thereof, or other suitable material. Further, the high-k gate dielectric layer may include a multiple layer configuration such as HfO2/SiO2 or HfO2/SiON.

The gate structure 212 may further include a gate electrode 218 formed over the gate dielectric layer 216. Forming the gate electrode 218 may include forming a plurality of layers. For example, an interface layer, a dielectric layer, a high-k layer, a capping layer, a work function metal, and a gate electrode. Processing may utilize a gate first process or a gate last process. The gate first process includes forming a final gate structure. The gate last process includes forming a dummy gate structure and, in subsequent processing, performing a gate replacement process that includes removing the dummy gate structure and forming final gate structure according to the above described approach.

The gate structure 212 includes gate spacers 220 formed on the sidewalls of the gate electrode 218 and on the substrate 210. The gate spacers 220 are formed by any suitable process to any suitable thickness. The gate spacers 220 include a dielectric material, such as silicon nitride, silicon oxide, silicon oxynitride, other suitable materials, and/or combinations thereof.

With further reference to FIG. 2, formed over the substrate 210 is a first dielectric layer 222 overlying the gate structure 212. The first dielectric layer 222 may include silicon oxide, plasma-enhanced oxide (PEOX), silicon oxynitride, a low-k material, or other suitable materials. The first dielectric layer 222 may be formed by chemical vapor deposition (CVD), high density plasma CVD (HDP-CVD), spin-on, physical vapor deposition (PVD or sputtering), plasma enhanced CVD, or other suitable methods. The CVD process, for example, may use chemicals including Hexachlorodisilane (HCD or Si2Cl6), Dichlorosilane (DCS or SiH2Cl2), Bis(TertiaryButylAmino) Silane (BTBAS or C8H22N2Si) and Disilane (DS or Si2H6). In the present embodiment, the top surface of the dielectric layer 222 is planarized by a chemical mechanical polishing (CMP) process. The CMP process stops on the top surface of the gate structure 212. In alternative embodiments, a CMP process is not performed.

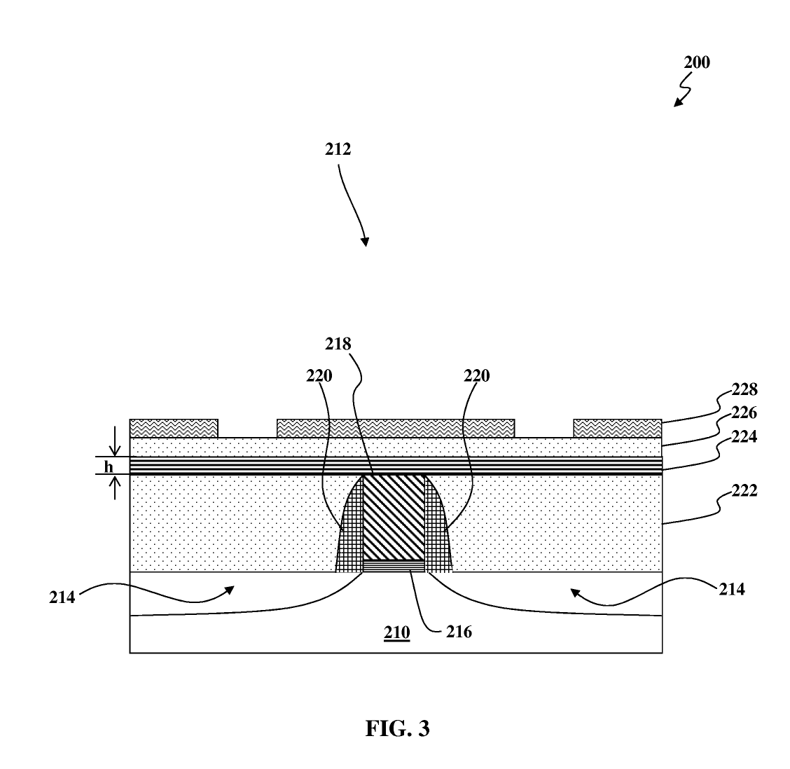

Referring to FIG. 3, an intermediate layer 224 is formed over the first dielectric layer 222 and over the gate structure 218. In the present embodiment, the intermediate layer 224 is a hard mask layer. In alternative embodiments, the intermediate layer 224 is any suitable layer. Although the present disclosure will continue with an example where the intermediate layer 224 is a hard mask, it is understood that the disclosure is not limited to this embodiment unless explicitly claimed. The hard mask 224 may be formed by any suitable process to any suitable thickness/height (h). For example, the height (h) of the insulating layer 214 may range from about 30 angstroms to about 300 angstroms. Formed over the hard mask 224 is a sacrificial dielectric layer 226. The sacrificial dielectric layer 226 may serve to protect the underlying hard mask 224 and aid in processing. The sacrificial dielectric layer 226 may include silicon oxide, plasma-enhanced oxide (PEOX), silicon oxynitride, a low-k material, or other suitable materials. The sacrificial dielectric layer 226 may be formed by chemical vapor deposition (CVD), high density plasma CVD (HDP-CVD), spin-on, physical vapor deposition (PVD or sputtering), plasma enhanced CVD, or other suitable methods. The CVD process, for example, may use chemicals including Hexachlorodisilane (HCD or Si2Cl6), Dichlorosilane (DCS or SiH2Cl2), Bis(TertiaryButylAmino) Silane (BTBAS or C8H22N2Si) and Disilane (DS or Si2H6).

Still referring to FIG. 3, formed over the sacrificial dielectric layer 226 is a patterned photoresist layer 228. The photoresist layer 228 may be patterned by any suitable process. The photoresist layer 228 patterning may include processing steps of soft baking, mask aligning, exposing pattern, post-exposure baking, developing photoresist, and hard baking. The patterning may also be implemented or replaced by other proper methods, such as maskless photolithography, electron-beam writing, ion-beam writing, and molecular imprint. In further embodiments, the patterned photoresist layer 228 includes an underlying hard mask.

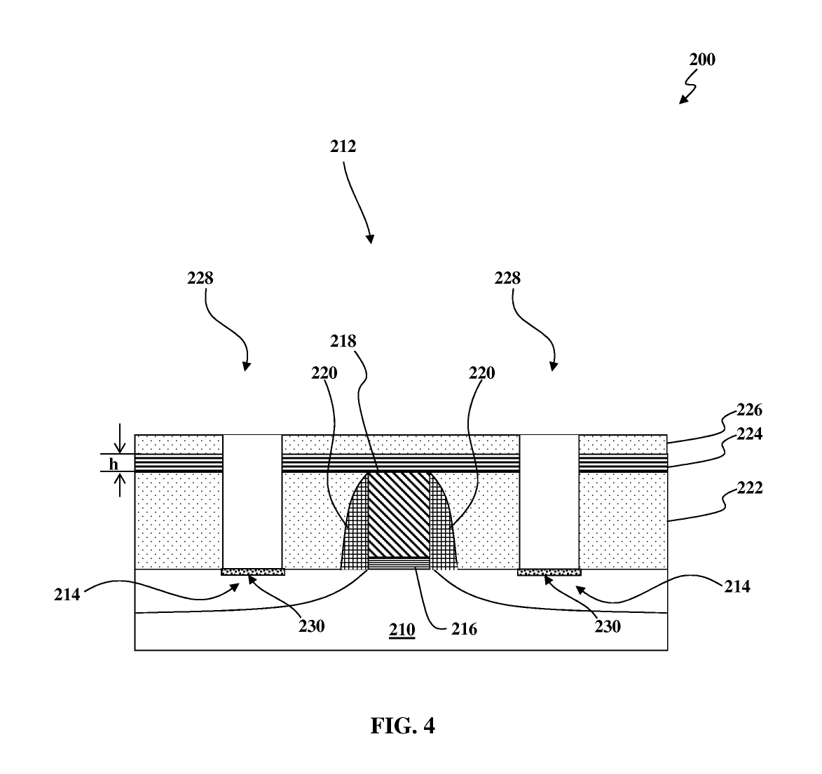

Referring to FIG. 4, a first set of trenches 228 are formed by etching portions of the sacrificial dielectric layer 226, the hard mask 224, and the first dielectric layer 222 thereby exposing a top surface of the substrate 210. The etching process uses the patterned photoresist layer 228 to define the area to be etched. The etching process may be a single or a multiple step etching process. Further, the etching process may include wet etching, dry etching, or a combination thereof. The dry etching process may be an anisotropic etching process. The etching process may use reactive ion etch (RIE) and/or other suitable process. In one example, a dry etching process is used that includes a chemistry including fluorine-containing gas. In furtherance of the example, the chemistry of the dry etch includes CF4, SF6, or NF3. In the present embodiment, the etching process is a three step etching process where a first process is used to etch the sacrificial dielectric layer 226, a second process is used to etch the hard mask 224, and a third process is used to etch the first dielectric layer 222.

Still referring to FIG. 4, after the etching process, the patterned photoresist layer 228 may be removed by any suitable process. For example, the patterned photoresist layer 228 may be removed by a liquid “resist stripper”, which chemically alters the resist so that it no longer adheres to the underlying hard mask. Alternatively, the patterned photoresist layer 228 may be removed by a plasma containing oxygen, which oxidizes it.

With continued reference to FIG. 4, formed over the S/D features 214 is a silicide layer 230. The silicide layer 230 may be used to reduce the contact resistance of subsequently formed contacts/interconnects. Forming the silicide layer 230 may include depositing a metal layer on the S/D features 214. The metal layer for silicide may include titanium, nickel, cobalt, platinum, palladium tungsten, tantalum, erbium, or any suitable material. The metal layer contacts the silicon within the S/D features 214 of the substrate 210. An annealing process with a proper temperature is applied to the semiconductor device 200 such that the metal layer and the silicon of the S/D features 214 react to form silicide. The formed silicide layer 230 may be in any proper composition and phase, determined by various parameters including the annealing temperature and the thickness of the metal layer. In some embodiments, a metal barrier may be formed over the silicide layer, thereby improving reliability. Because the sacrificial dielectric layer 226 overlies the hard mask 224, forming the silicide layer 230 does not affect the hard mask 224 (e.g., no metal is deposited on the hard mask 224).

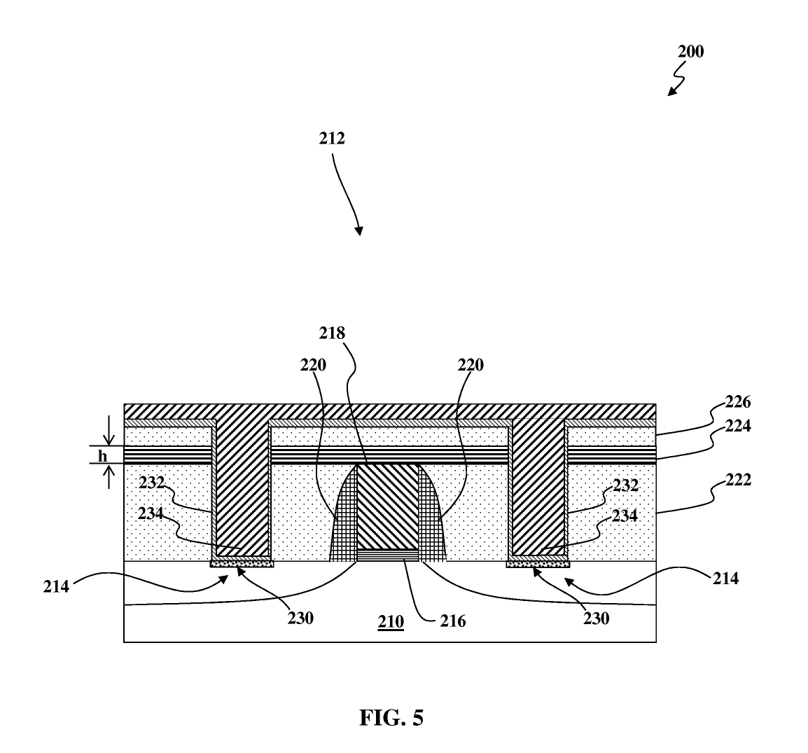

Referring to FIG. 5, a barrier layer 232 is formed over the semiconductor device 200 and overlying the silicide layer 230 within the trenches 228. The barrier layer 232 may be a multilayer barrier layer that includes alternating layers of titanium (Ti) and titanium nitride (TiN), or any appropriate material. Deposited over the barrier layer 232 and within the trenches 228 is a conductive material used to form a first interconnect structure 234. The conductive material of the first interconnect structures 234 may include a metal such as aluminum (Al), tungsten (W), and copper (Cu). The first interconnect structures 234 may be formed by chemical vapor deposition (CVD), physical vapor deposition (PVD), atomic layer deposition (ALD), high density plasma CVD (HDPCVD), plating, other suitable methods, and/or combinations thereof. As illustrated, the first interconnect structures 234 are disposed over the barrier layer 232 and over the silicide layer 230 and in electrical contact with the S/D features 214. Because the sacrificial dielectric layer 226 overlies the hard mask 224, forming the first interconnect structure 234 does not affect the hard mask 224 (e.g., no conductive material is deposited on the hard mask 224).

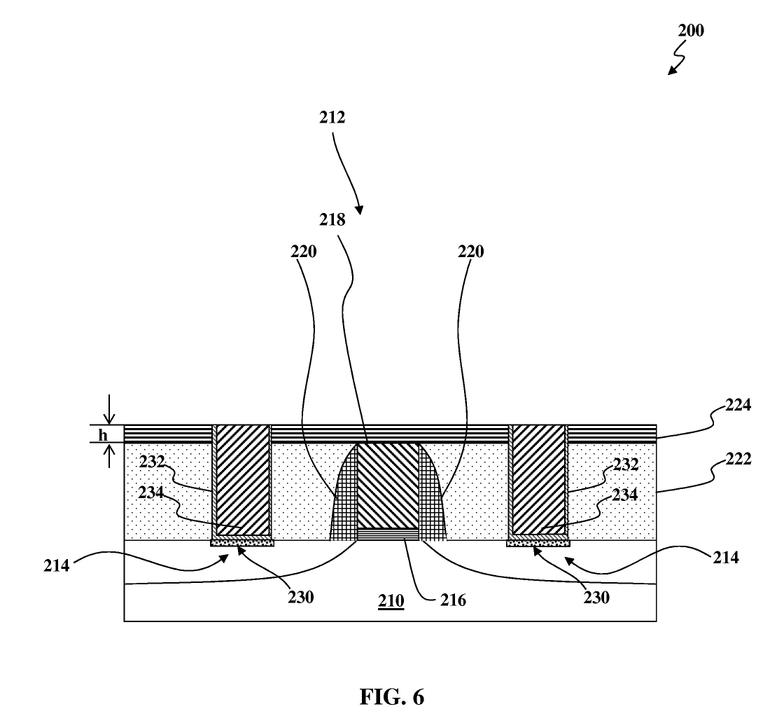

Referring to FIG. 6, a CMP process is performed to remove excess material on the top of the semiconductor device 200 and to planarize a top surface of the semiconductor device 200. The CMP process stops on the hard mask 224.

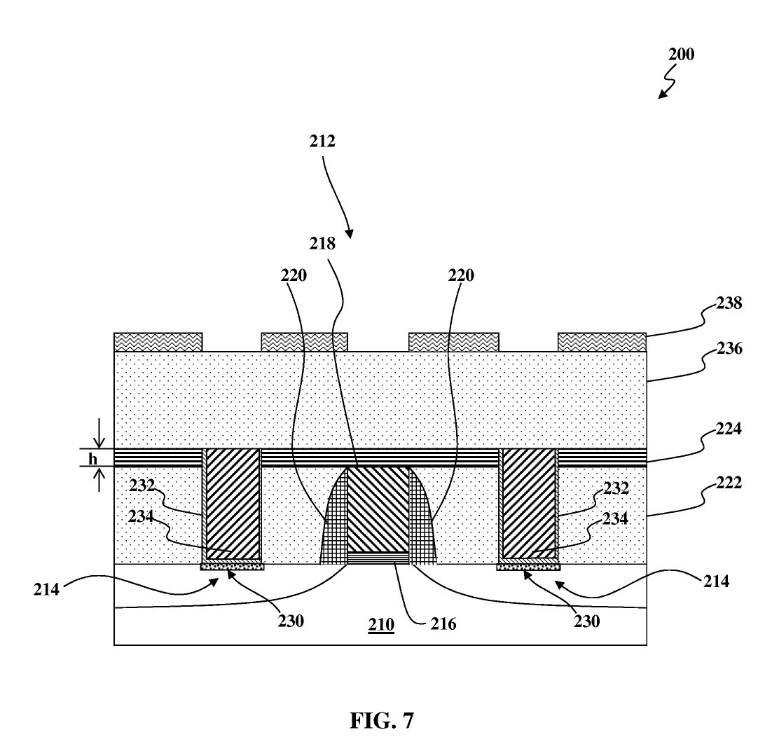

Referring to FIG. 7, a second dielectric layer 236 and a second patterned photoresist layer 238 are formed. The second dielectric layer 236 is substantially similar to the first dielectric layer 222 in terms of material composition and formation. In alternative embodiments, they are different. The second patterned photoresist layer 238 is substantially similar to the first photoresist layer 228 (see FIG. 2) in terms of material composition and formation. In alternative embodiments, they are different.

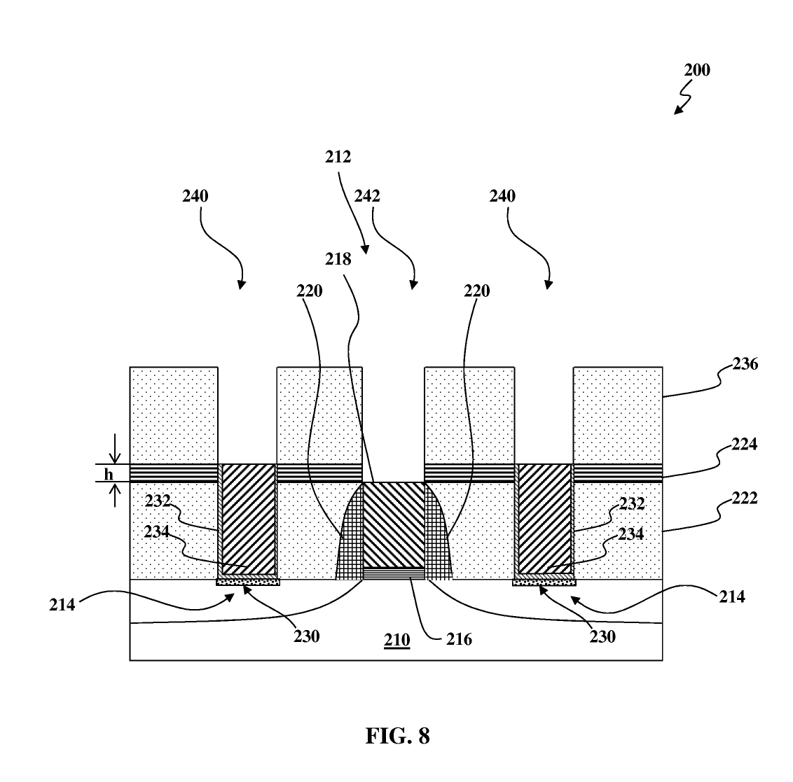

Referring to FIG. 8, a second set of trenches 240 are formed by etching the second dielectric layer 236 thereby exposing a top surface of the first interconnect structure 234 and a third trench 242 is formed by etching the second dielectric layer 236 and the hard mask 224 thereby exposing a top surface of the gate electrode 218. The etching process uses the patterned photoresist layer 228 to define the area to be etched. The etching processes may be a single or multiple step etching processes. Further, the etching process may include wet etching, dry etching, or a combination thereof. The dry etching process may be an anisotropic etching process. The etching process may use reactive ion etch (RIE) and/or other suitable process. In one example, a dry etching process is used that includes a chemistry including fluorine-containing gas. In furtherance of the example, the chemistry of the dry etch includes CF4, SF6, or NF3. In the present embodiment, the etching process to form the second set of trenches 240 is a single step etching process and the etching process to form the third trench 242 is a two-step etching process. In the two-step etching process to form the third trench 242, a first etching is used to etch second dielectric layer 236 and a second etch is used to etch the hard mask 224 over the gate electrode 218.

Still referring to FIG. 8, after the etching process, the second patterned photoresist layer 238 may be removed by any suitable process. For example, the second patterned photoresist layer 238 may be removed by a liquid “resist stripper”, which chemically alters the resist so that it no longer adheres to the underlying hard mask. Alternatively, the second patterned photoresist layer 238 may be removed by a plasma containing oxygen, which oxidizes it.

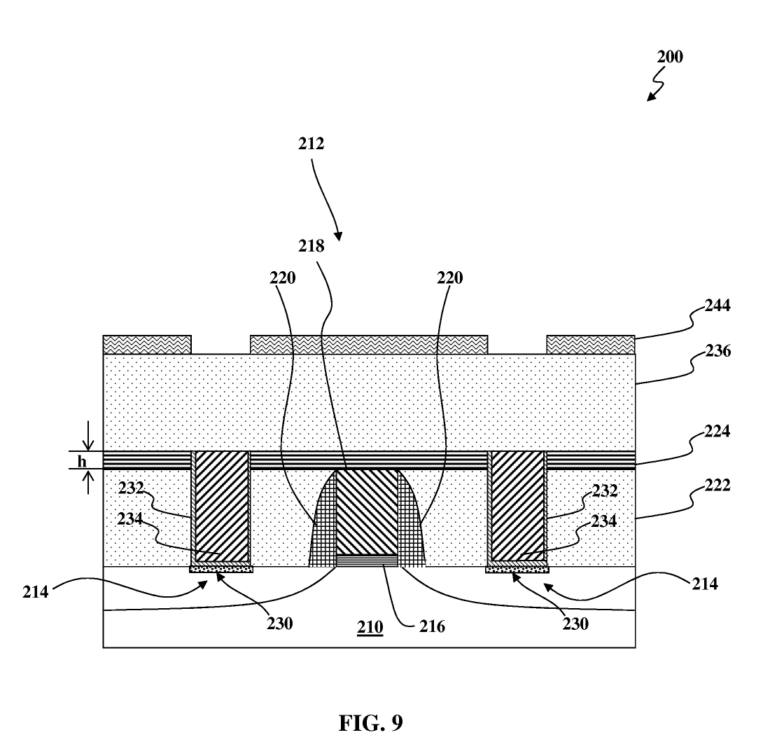

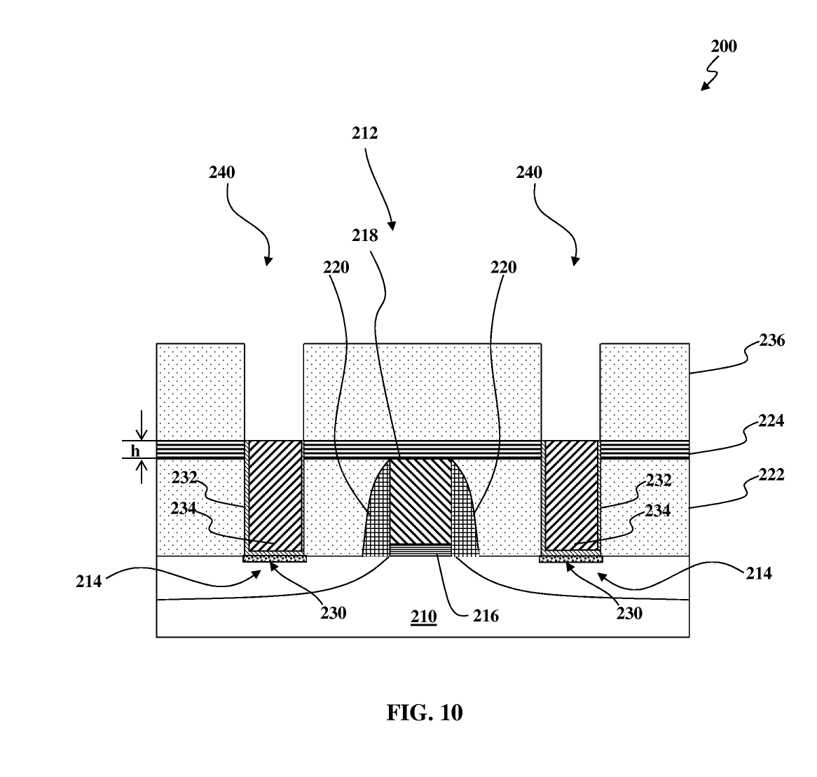

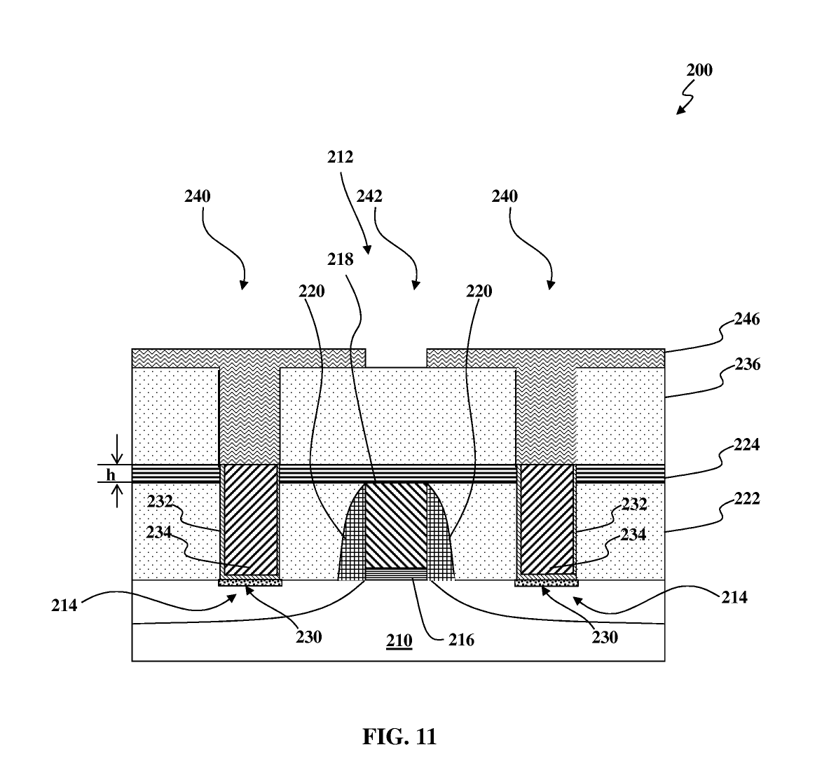

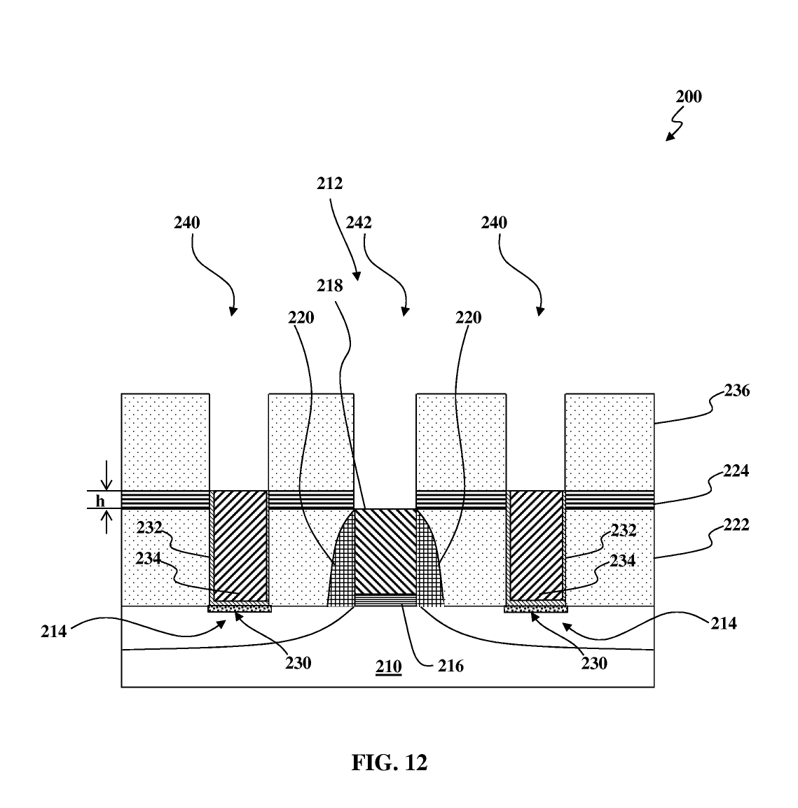

Referring to FIGS. 9-12, in alternative embodiments, rather than using a single photoresist/etching process as described above with reference to FIGS. 7-8, a separate photoresists/etching processes is used to form the second set of trenches 240 and a separate photoresist/etching process is used to form the third trench 242. For example, as illustrated in FIG. 9, a patterned photoresist 244 is provided having openings defined over the S/D regions 214. Thereafter, as illustrated in FIG. 10, an etching process is used to etch the second dielectric layer 236 thereby exposing a top surface of the first interconnect structure 234 and forming the second set of trenches 240. In furtherance of the example, as illustrated in FIG. 11, another patterned photoresist 246 is provided having an opening defined over the gate electrode 218. The patterned photoresist 246 may substantially fill the second set of trenches 240. After providing the pattered photoresist 246, as illustrated in FIG. 12, an etching process is used to etch the second dielectric layer 236 and the hard mask 224, thereby exposing a top surface of the gate electrode 218. The two separate patterning/etching processes for forming the second set of trenches 240 and the third trench 242, as provided in FIGS. 9-12, may be utilized where the resolution of photolithography is limited such that the patterns have close proximities which cannot be accurately defined (e.g., the critical dimensions are not met by a single etching process). It is understood that the photoresists 244 and 246, described with reference to FIGS. 9-12, may be similar to the photoresist 238 in terms of material composition and formation. Also, it is understood that the etching processes, described with reference to FIGS. 9-12, may be similar to the etching process described with reference to FIGS. 7-8.

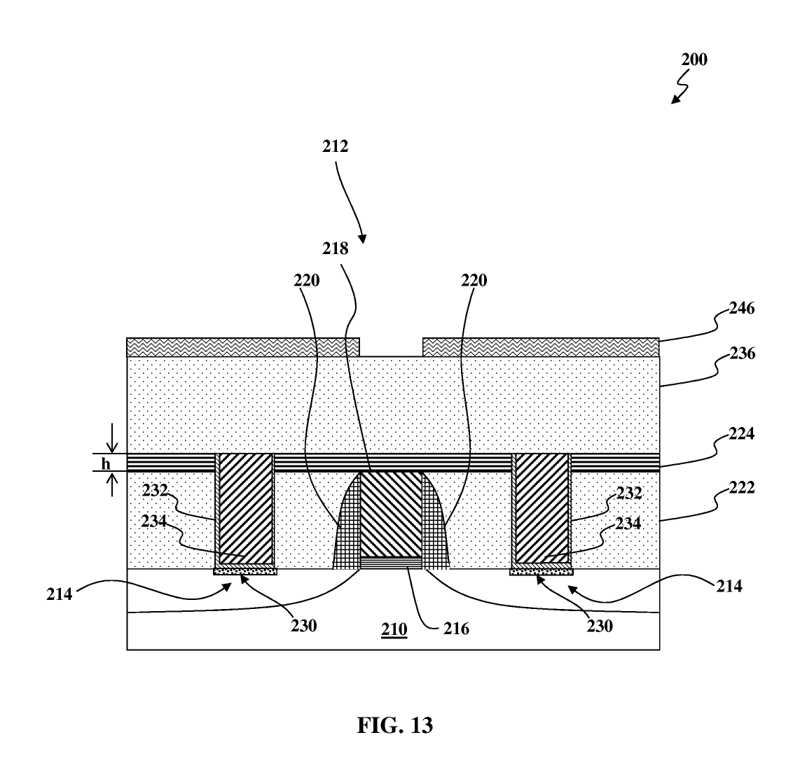

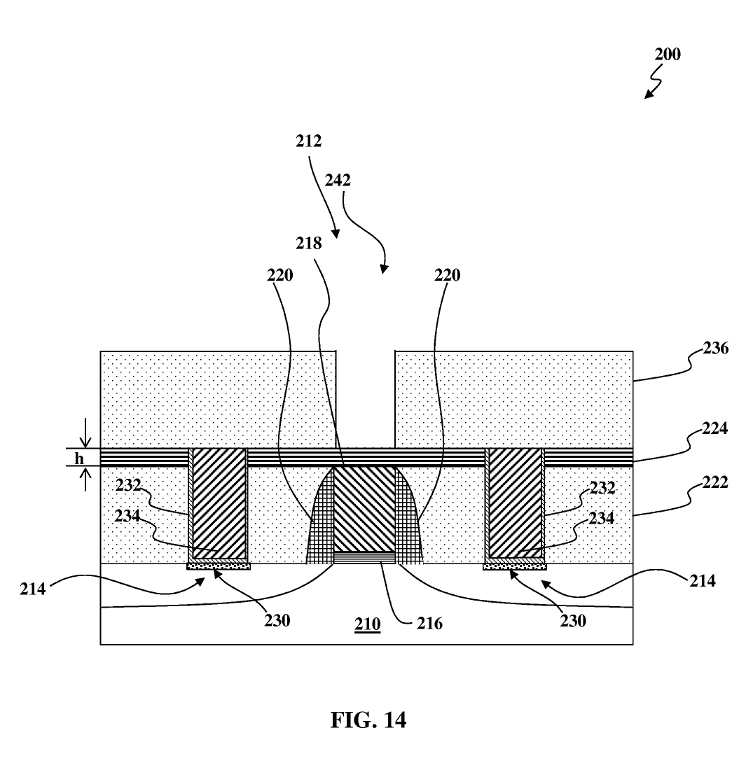

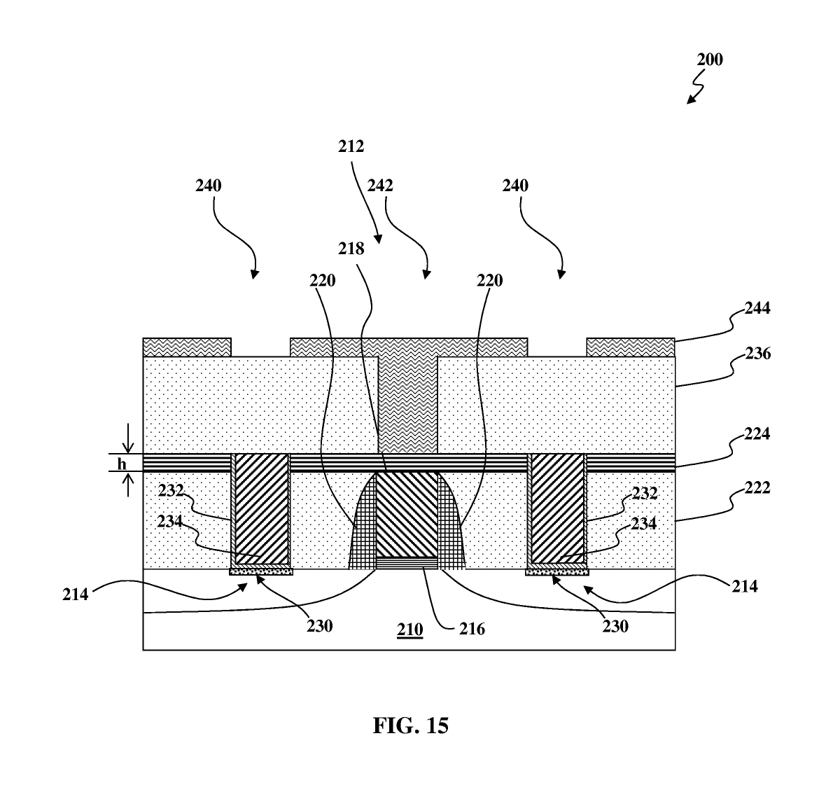

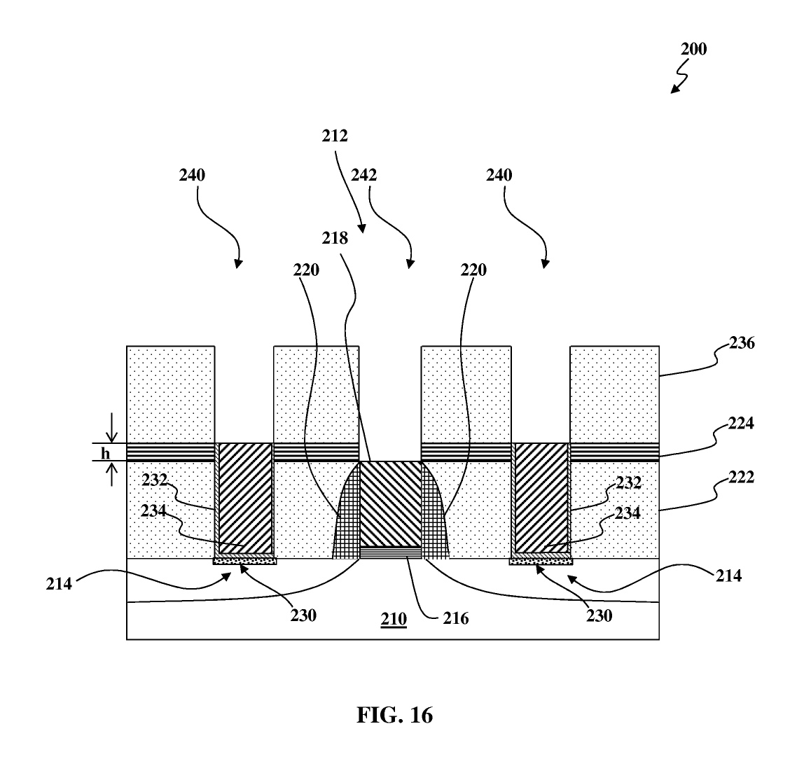

Referring to FIGS. 13-16 in alternative embodiments, rather than forming the second trench 240 first and then the third trench 242 as illustrated in FIG. 9-12, the third trench 242 is formed first and then the second trench 240 is formed thereafter. For example, as illustrated in FIG. 13, a patterned photoresist 246 is provided having openings defined over the gate electrode 218. Thereafter, as illustrated in FIG. 14, an etching process is used to etch the second dielectric layer 236 and the hard mask 224, thereby exposing a top surface of the gate electrode 218 and forming a third trench 242. In furtherance of the example, as illustrated in FIG. 15, another patterned photoresist 244 is provided having an opening defined over the S/D regions 214. The patterned photoresist 244 may substantially fill the third trench 242. After providing the pattered photoresist 244, as illustrated in FIG. 16, an etching process is used to etch the second dielectric layer 236, thereby exposing a top surface of the first interconnect structure 234 and forming a second set of trenches 240. The two separate patterning/etching processes for forming the second set of trenches 240 and the third trench 242, as provided in FIGS. 13-16, may be utilized where the resolution of photolithography is limited such that the patterns have close proximities which cannot be accurately defined (e.g., the critical dimensions are not met by a single etching process). It is understood that the photoresists 244 and 246, described with reference to FIGS. 13-16, may be similar to the photoresist 238 in terms of material composition and formation. Also, it is understood that the etching processes, described with reference to FIGS. 13-16, may be similar to the etching process described with reference to FIGS. 7-8.

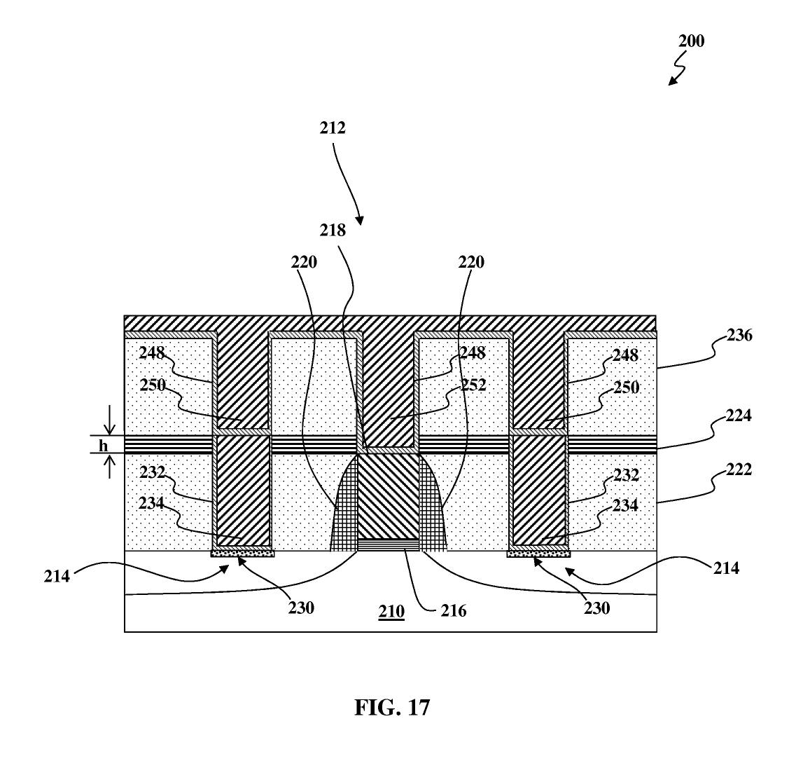

Referring to FIG. 17, a barrier layer 248 is formed over the semiconductor device 200 within the trenches second trench 240 and third trench 242 of FIGS. 8, 12 and 16. The barrier layer 248 may be a multilayer barrier layer that includes alternating layers of titanium (Ti) and titanium nitride (TiN), or any appropriate material. Deposited over the barrier layer 248 and within the trenches 240 is a conductive material used to form a second interconnect structure 250 and a gate electrode 218 interconnect structure 252 in the third trench 242 of FIGS. 8, 12 and 16. The conductive material of the second interconnect structure 250 and the gate electrode 218 interconnect structure 252 may include a metal such as aluminum (Al), tungsten (W), and copper (Cu). The material of the second interconnect structure 250 and the gate electrode 218 interconnect structure 252 may be formed by chemical vapor deposition (CVD), physical vapor deposition (PVD), atomic layer deposition (ALD), high density plasma CVD (HDPCVD), plating, other suitable methods, and/or combinations thereof.

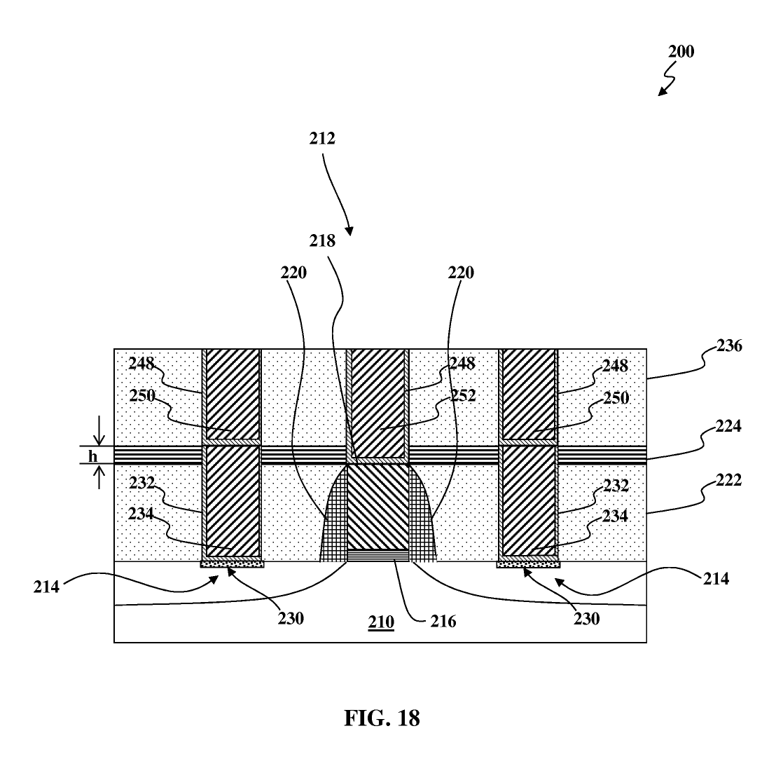

Referring to FIG. 18, a CMP process is performed to remove excess interconnect structure material on the top of the semiconductor device 200 and to planarize a top surface of the semiconductor device 200.

As illustrated in FIG. 18, the semiconductor device 200 includes a substrate 210 having a gate structure 212. The substrate 210 further includes a first dielectric layer 222 having a first interconnect structure 234 in electrical contact with the S/D features 214. The first interconnect structure 234 includes a top surface in a plane that is different (i.e., higher) than a top surface of the gate structure 212. The difference in height is substantially the same as the height (h) of the hard mask 224. Formed over the first dielectric layer 222 is a second dielectric layer 236 including a second interconnect structure 250 in electrical contact with the first interconnect structure 234. The second interconnect structure 250 is formed over the barrier layer 242 and over the first interconnect structure 234 and in electrical contact with the S/D features 214. A bottom surface of the barrier layer 242, underlying the second interconnect structure 250, is substantially coplanar with a top surface of the hard mask 224. The second dielectric layer 236 also includes interconnect structure 252 formed over the gate electrode 218 and in electrical contact with the gate structure 212. A bottom surface of the barrier layer 242, underlying the interconnect structure 252, is substantially coplanar with a top surface of the gate structure 212.

The disclosed semiconductor device 200 may include additional features, which may be formed by subsequent processing. For example, subsequent processing may further form various contacts/vias/lines and multilayer interconnect features (e.g., metal layers and interlayer dielectrics) on the substrate, configured to connect the various devices (such as transistors, resistors, capacitors, etc . . . ), features, and structures of the semiconductor device 200. The additional features may provide electrical interconnection to the semiconductor device 200. For example, a multilayer interconnection includes vertical interconnects, such as conventional vias or contacts, and horizontal interconnects, such as metal lines. The various interconnection features may implement various conductive materials including copper, tungsten, and/or silicide.

The disclosed semiconductor device 200 may be used in various applications such as digital circuit, imaging sensor devices, a hetero-semiconductor device, dynamic random access memory (DRAM) cell, a single electron transistor (SET), and/or other microelectronic devices (collectively referred to herein as microelectronic devices). Of course, aspects of the present disclosure are also applicable and/or readily adaptable to other types of transistors, including single-gate transistors, double-gate transistors, and other multiple-gate transistors, and may be employed in many different applications, including sensor cells, memory cells, logic cells, and others.

The above method 100 provides for an improved process and semiconductor device 200. The above method 100 allows for improved topography during the manufacturing process thereby allowing for proper photolithography/etching processes which results in improved device critical dimensions and device performance. The method 100 can be easily implemented into current manufacturing process and technology, thereby lowering cost and minimizing complexity. Different embodiments may have different advantages, and no particular advantage is necessarily required of any embodiment.

Thus, provided is a semiconductor device. The exemplary semiconductor device includes a substrate including a gate structure separating source and drain (S/D) features. The semiconductor device further includes a first dielectric layer formed over the substrate, the first dielectric layer including a first interconnect structure in electrical contact with the S/D features. The semiconductor device further includes an intermediate layer formed over the first dielectric layer, the intermediate layer having a top surface that is substantially coplanar with a top surface of the first interconnect structure. The semiconductor device further includes a second dielectric layer formed over the intermediate layer, the second dielectric layer including a second interconnect structure in electrical contact with the first interconnect structure and a third interconnect structure in electrical contact with the gate structure.

In some embodiments, the semiconductor device further includes a silicide layer disposed on the S/D features, the silicide layer being interposed between the S/D features and the first interconnect structure. In various embodiments, the semiconductor device further includes a barrier layer disposed on silicide layer, the barrier layer being interposed between the silicide layer and the first interconnect structure.

In some embodiments, the intermediate layer includes a hard mask. In various embodiments, the first, second, and third interconnect structures include a material selected from the group consisting of aluminum (Al), tungsten (W), and copper (Cu). In certain embodiments, the intermediate layer has a height that ranges from about 30 Angstroms to about 300 Angstroms. In further embodiments, the gate structure includes a gate dielectric and a gate electrode, the gate electrode being in electrical contact with the third interconnect structure.

Also provided is an alternative embodiment of a semiconductor device. The semiconductor device includes a substrate including a gate structure traversing a channel region and separating source and drain (S/D) features, the gate structure including a gate electrode, the gate structure having a top surface in a first plane. The semiconductor further includes a first dielectric layer formed over the S/D features. The semiconductor further includes a first interconnect structure extending through the first dielectric layer and through an intermediate layer formed over the first dielectric layer, the first interconnect being in electrical contact with the S/D features, the first interconnect structure having a top surface in a second plane different from the first plane of the top surface of the gate structure. The semiconductor further includes a second dielectric layer formed over the intermediate layer. The semiconductor further includes a second interconnect structure extending through the second dielectric layer, the second interconnect being in electrical contact with the first interconnect structure. The semiconductor further includes a third interconnect structure extending through the second dielectric layer and through the intermediate layer, the third interconnect structure being in electrical contact with the gate structure

In some embodiments, the semiconductor device further includes a silicide layer disposed on the S/D features, the silicide layer being interposed between the S/D features and the first interconnect structure. In various embodiments, the semiconductor device further includes a barrier layer disposed on silicide layer, the barrier layer being interposed between the silicide layer and the first interconnect structure.

In some embodiments, the intermediate layer includes a hard mask, and the intermediate layer includes a hard mask. In various embodiments, the first, second, and third interconnect structures include a material selected from the group consisting of aluminum (Al), tungsten (W), and copper (Cu).

Also provided is a method of forming a semiconductor device. The exemplary method includes providing a substrate including a gate structure separating source and drain (S/D) features. The method further includes forming a first dielectric layer formed over the substrate, the first dielectric layer including a first interconnect structure in electrical contact with the S/D features. The method further includes forming an intermediate layer formed over the first dielectric layer, the intermediate layer having a top surface that is substantially coplanar with a top surface of the first interconnect structure. The method further includes forming a second dielectric layer formed over the intermediate layer, the second dielectric layer including a second interconnect structure in electrical contact with the first interconnect structure and a third interconnect structure in electrical contact with the gate structure.

In some embodiments, the method further includes forming a silicide layer over the S/D features, the silicide layer being interposed between the S/D features and the first interconnect structure. In various embodiments, the method further includes forming a barrier layer over the silicide layer, the barrier layer being interposed between the silicide layer and the first interconnect structure.

In some embodiments, forming the intermediate layer includes forming a hard mask. In various embodiments, the first, second, and third interconnect structures include a material selected from the group consisting of aluminum (Al), tungsten (W), and copper (Cu). (Al), tungsten (W), and copper (Cu). In certain embodiments, the intermediate layer has a thickness that ranges from about 30 Angstroms to about 300 Angstroms. In further embodiments, the gate structure includes a gate dielectric and a gate electrode. In some embodiments, the substrate is one of a bulk silicon or a silicon-on-insulator (SOI).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate including a gate structure separating source and drain (S/D) features;
a first dielectric layer formed over the substrate, the first dielectric layer including a first interconnect structure in electrical contact with the S/D features;
an intermediate layer formed over the first dielectric layer, the intermediate layer having a top surface that is substantially coplanar with a top surface of the first interconnect structure; and
a second dielectric layer formed over the intermediate layer, the second dielectric layer including a second interconnect structure in electrical contact with the first interconnect structure and a third interconnect structure in electrical contact with the gate structure.

2. The semiconductor device of claim 1 further comprising a silicide layer disposed on the S/D features, the silicide layer being interposed between the S/D features and the first interconnect structure.

3. The semiconductor device of claim 2 further comprising a barrier layer disposed on silicide layer, the barrier layer being interposed between the silicide layer and the first interconnect structure.

4. The semiconductor device of claim 1 wherein the intermediate layer includes a hard mask.

5. The semiconductor device of claim 1 wherein the first, second, and third interconnect structures include a material selected from the group consisting of aluminum (Al), tungsten (W), and copper (Cu).

6. The semiconductor device of claim 1 wherein the intermediate layer has a height that ranges from about 30 Angstroms to about 300 Angstroms.

7. The semiconductor device of claim 1 wherein the gate structure includes a gate dielectric and a gate electrode, the gate electrode being in electrical contact with the third interconnect structure.

8. A semiconductor device comprising:
a substrate including a gate structure traversing a channel region and separating source and drain (S/D) features, the gate structure including a gate electrode, the gate structure having a top surface in a first plane;
a first dielectric layer formed over the S/D features;
a first interconnect structure extending through the first dielectric layer and through an intermediate layer formed over the first dielectric layer, the first interconnect being in electrical contact with the S/D features, the first interconnect structure having a top surface in a second plane different from the first plane of the top surface of the gate structure;
a second dielectric layer formed over the intermediate layer;
a second interconnect structure extending through the second dielectric layer, the second interconnect being in electrical contact with the first interconnect structure; and
a third interconnect structure extending through the second dielectric layer and through the intermediate layer, the third interconnect structure being in electrical contact with the gate structure.

9. The semiconductor device of claim 8 further comprising a silicide layer disposed on the S/D features, the silicide layer being interposed between the S/D features and the first interconnect structure.

10. The semiconductor device of claim 9 further comprising a barrier layer disposed on silicide layer, the barrier layer being interposed between the silicide layer and the first interconnect structure.

11. The semiconductor device of claim 8 wherein the intermediate layer includes a hard mask, and
wherein the intermediate layer includes a hard mask.

12. The semiconductor device of claim 8 wherein the first, second, and third interconnect structures include a material selected from the group consisting of aluminum (Al), tungsten (W), and copper (Cu).

13. A method of manufacturing comprising:
providing a substrate including a gate structure separating source and drain (S/D) features;
forming a first dielectric layer formed over the substrate, the first dielectric layer including a first interconnect structure in electrical contact with the S/D features;
forming an intermediate layer formed over the first dielectric layer, the intermediate layer having a top surface that is substantially coplanar with a top surface of the first interconnect structure; and
forming a second dielectric layer formed over the intermediate layer, the second dielectric layer including a second interconnect structure in electrical contact with the first interconnect structure and a third interconnect structure in electrical contact with the gate structure.

14. The method of claim 13 further comprising forming a silicide layer over the S/D features, the silicide layer being interposed between the S/D features and the first interconnect structure.

15. The method of claim 14 further comprising forming a barrier layer over the silicide layer, the barrier layer being interposed between the silicide layer and the first interconnect structure.

16. The method of claim 13 wherein forming the intermediate layer includes forming a hard mask.

17. The method of claim 13 wherein the first, second, and third interconnect structures include a material selected from the group consisting of aluminum (Al), tungsten (W), and copper (Cu). (Al), tungsten (W), and copper (Cu).

18. The method of claim 13 wherein the intermediate layer has a thickness that ranges from about 30 Angstroms to about 300 Angstroms.

19. The method of claim 13 wherein the gate structure includes a gate dielectric and a gate electrode.

20. The method of claim 13 wherein the substrate is one of a bulk silicon or a silicon-on-insulator (SOI).
